(19) United States
(12) Patent Application Publication
(10) Pub. No.: US 2026/0123489 A1
(43) Pub. Date: Apr. 30, 2026

(54) ELECTRONIC STRUCTURE AND MANUFACTURING METHOD THEREOF

(71) Applicant: SILICONWARE PRECISION INDUSTRIES CO., LTD., Taichung City (TW)

(72) Inventors: Yi-Chun LAI, Taichung City (TW); Hsuan-Jen WANG, Taichung City (TW)

(21) Appl. No.: 18/966,581

(22) Filed: Dec. 3, 2024

(30) Foreign Application Priority Data
Oct. 24, 2024 (TW) 113140616

(51) Int. Cl. H01L 23/498; H01L 21/48; H01L 25/11

(52) U.S. Cl. CPC H10W 70/685; H10W 70/05; H10W 70/093; H10W 70/65; H10W 90/701; H10W 90/00

(57) ABSTRACT

An electronic structure and a manufacturing method thereof are provided. A plurality of first conductive bumps and a plurality of second conductive bumps are respectively formed on a first side and a second side of an electronic body, a reinforcing layer is formed on the first side having the plurality of first conductive bumps, and the height of each of the first conductive bumps is greater than the thickness of the reinforcing layer, so that each of the first conductive bumps protrudes and is exposed from the reinforcing layer, thereby reducing the warpage problem of the electronic structure via the reinforcing layer.

### CROSS-REFERENCE TO RELATED APPLICATIONS

The present application is based upon and claims the right of priority to TW Patent Application No. 113140616, filed October 24, 2024, the disclosure of which is hereby incorporated by reference herein in its entirety for all purposes

### BACKGROUND

### 1. Technical Field

The present disclosure relates to a semiconductor component, and more particularly, to an electronic structure and a manufacturing method thereof.

### 2. Description of Related Art

In order to ensure the continued miniaturization and multi-functionality of electronic products and communication equipment, semiconductor packaging needs to develop towards miniaturization to facilitate the connection of multiple pins. To this end, the industry has developed many advanced process packaging technologies. For example, in advanced process packaging, commonly used packaging types such as 2.5D packaging process, Fan-Out Embedded Bridge (FO-EB) process, and others.

FIG. 1 is a schematic cross-sectional view of a conventional semiconductor package 1. As shown in FIG. 1, a wiring structure 14 on a carrier board 1b is provided with an electronic structure 1a and a plurality of conductive pillars 13, wherein the electronic structure 1a includes an electronic body 11, a plurality of conductive bumps 111, a circuit portion 12, a plurality of external bumps 122 and a protective layer 19. A plurality of conductive through holes 110 are formed in the electronic body 11 to connect a first surface 11a and a second surface 11b. The plurality of conductive bumps 111 are formed on the first surface 11a of the electronic body 11 and are electrically connected to a plurality of conductive through holes 110. The circuit portion 12 is disposed on the second surface 11b of the electronic body 11 and includes at least one insulating layer 120 and conductive traces 121 bonded to the insulating layer 120. The plurality of external bumps 122 are formed on the circuit portion 12 and are electrically connected to the plurality of conductive through holes 110 via conductive traces 121. The protective layer 19 is formed on the first surface 11a of the electronic body 11 and covers the plurality of conductive bumps 111.

The above-mentioned electronic structure 1a is disposed on the wiring structure 14 via the plurality of external bumps 122. However, since the thickness of the electronic body 11 is very thin, the protective layer 19 is formed on the first surface 11a of the electronic body 11, and the difference in the coefficient of thermal expansion (CTE) between the protective layer 19 and the electronic body 11 is too large, the electronic structure 1a is prone to warpage and cracking, thereby leading to problems in the quality reliability and yield of subsequent products.

Therefore, how to overcome the above-mentioned drawbacks of the prior art has become an urgent issue to be solved.

### SUMMARY

In view of the various deficiencies of the prior art, the present disclosure provides an electronic structure, which comprises: an electronic body having a first side and a second side opposite to the first side; a plurality of first conductive bumps formed on the first side; a plurality of second conductive bumps formed on the second side; and a reinforcing layer formed on the first side, wherein a height of each of the plurality of first conductive bumps is greater than a thickness of the reinforcing layer, so that each of the plurality of first conductive bumps protrudes and is exposed from the reinforcing layer.

The present disclosure also provides a method for manufacturing an electronic structure, which comprises: providing an electronic body having a first side and a second side opposite to the first side, wherein a plurality of first conductive bumps are formed on the first side; forming a reinforcing layer on the first side, wherein a height of each of the plurality of first conductive bumps is greater than a thickness of the reinforcing layer, so that each of the plurality of first conductive bumps protrudes and is exposed from the reinforcing layer; and forming a plurality of second conductive bumps on the second side, and electrically connecting the plurality of second conductive bumps to the plurality of first conductive bumps.

In the aforementioned electronic structure and the manufacturing method thereof, a plurality of conductive vias are formed in the electronic body.

In the aforementioned electronic structure and the manufacturing method thereof, the plurality of second conductive bumps are electrically connected to the plurality of first conductive bumps via the plurality of conductive vias.

In the aforementioned electronic structure and the manufacturing method thereof, the plurality of first conductive bumps and the plurality of second conductive bumps are metal pillars.

In the aforementioned electronic structure and the manufacturing method thereof, a ratio of the thickness of the reinforcing layer to the height of each of the plurality of first conductive bumps is 0.4~0.8.

In the aforementioned electronic structure and the manufacturing method thereof, an adhesive layer is further formed on the reinforcing layer, so that the reinforcing layer and the adhesive layer cover the plurality of first conductive bumps.

In the aforementioned electronic structure and the manufacturing method thereof, the electronic structure serves as a bridge component for electrically connecting at least two electronic components.

In the aforementioned electronic structure and the manufacturing method thereof, the first side of the electronic body is further disposed on a first carrier via a first adhesive layer, wherein the plurality of first conductive bumps are formed on the first side, and then the second side is thinned, thereby exposing a plurality of conductive vias in the electronic body from the second side.

In the aforementioned electronic structure and the manufacturing method thereof, a conductive circuit is further formed on the second side of the electronic body and the conductive circuit is electrically connected to the conductive vias, and the plurality of second conductive bumps are formed on the conductive circuit, thereby electrically connecting the plurality of second conductive bumps to the plurality of first conductive bumps via the conductive circuit and the plurality of conductive vias.

In the aforementioned electronic structure and the manufacturing method thereof, the second side of the electronic body is further disposed on a second carrier via a second adhesive layer, wherein the plurality of second conductive bumps are formed on the second side, and the first carrier and the first adhesive layer are removed, thereby exposing the plurality of first conductive bumps from the reinforcing layer.

In the aforementioned electronic structure and the manufacturing method thereof, the first side of the electronic body is further disposed on a third carrier, wherein the plurality of first conductive bumps are formed on the first side, and the second carrier and the second adhesive layer are then removed.

As can be seen from the above, in the electronic structure and the manufacturing method thereof of the present disclosure, a reinforcing layer is formed on the first side of the electronic body, wherein there are a plurality of first conductive bumps on the first side, and the height of each first conductive bump is greater than the thickness of the reinforcing layer, so that each first conductive bump protrudes and is exposed from the reinforcing layer. Accordingly, the reinforcing layer improves the overall strength of the electronic structure, reduces the warpage problem, and avoids the problem of cracks caused by the electronic body being too thin during subsequent manufacturing processes.

### BRIEF DESCRIPTION OF THE DRAWINGS

FIG. 1 is a schematic cross-sectional view of a conventional semiconductor package.

FIG. 2A to FIG. 2F are schematic cross-sectional views illustrating a manufacturing method of an electronic structure according to the present disclosure.

FIG. 3A to FIG. 3C are schematic cross-sectional views illustrating a manufacturing method of an electronic package integrating the electronic structure of the present disclosure.

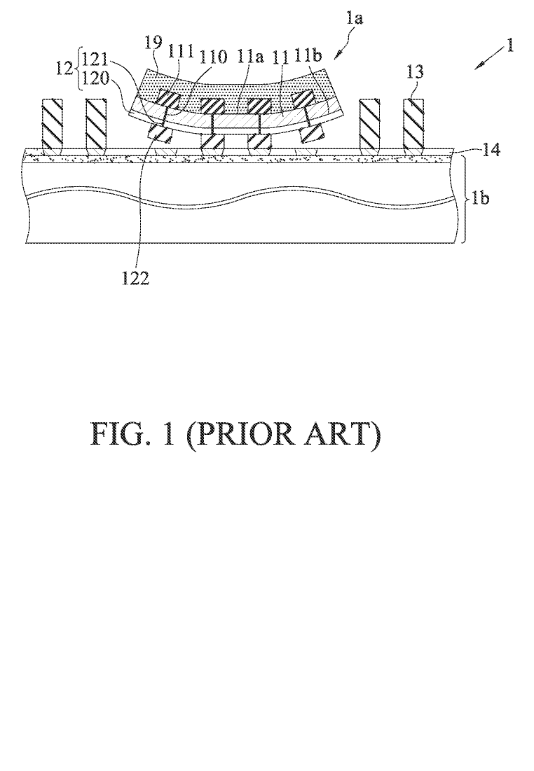

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

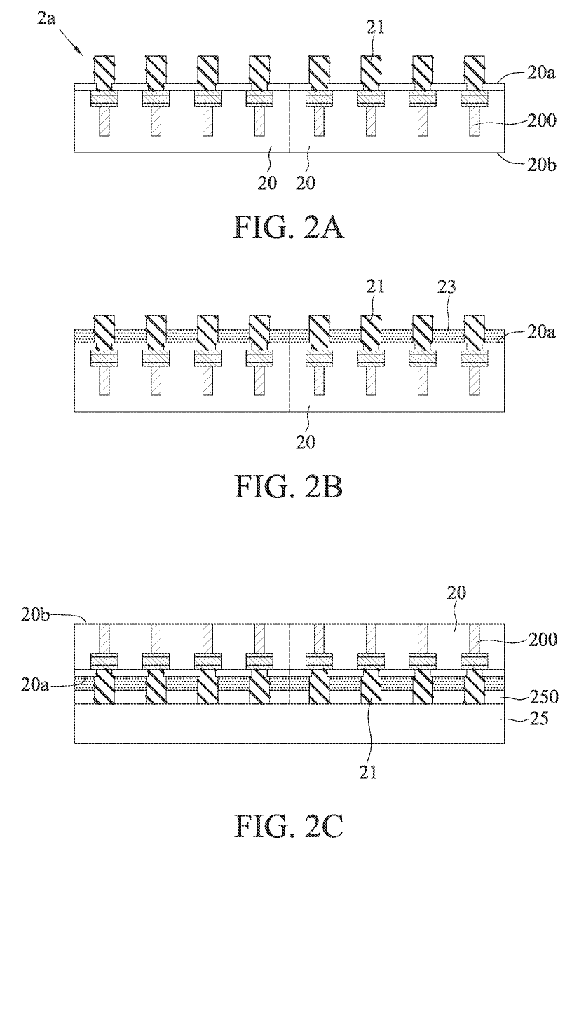

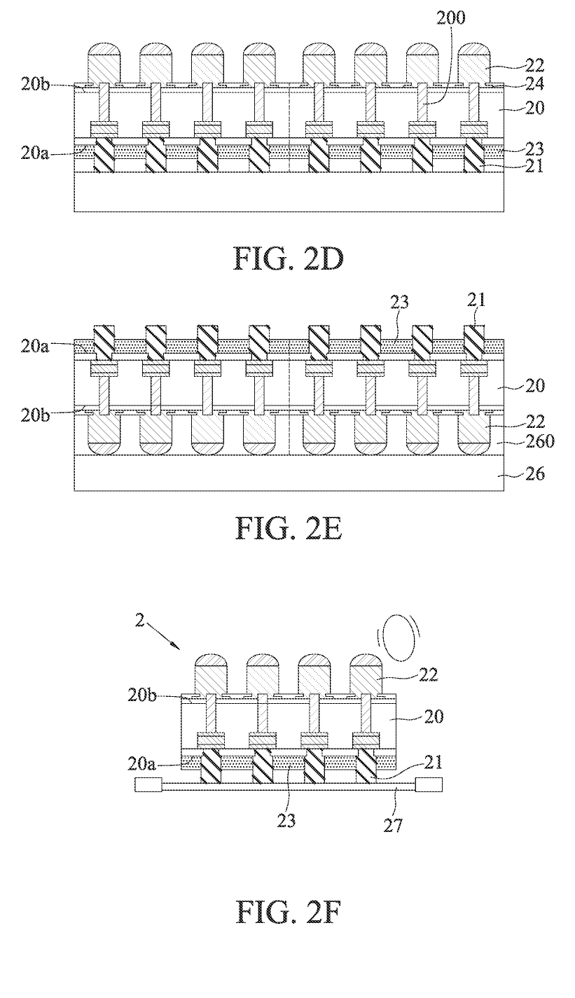

FIG. 2A to FIG. 2F are schematic cross-sectional views illustrating a manufacturing method of an electronic structure according to the present disclosure.

As shown in FIG. 2A, an electronic module 2a is provided, which includes a plurality of electronic bodies 20 (two electronic bodies 20 are shown in FIG. 2A). In one embodiment, the electronic module 2a is, for example, a wafer, and the plurality of electronic bodies 20 are, for example, semiconductor chips.

Each of the plurality of electronic bodies 20 has a first side 20a and a second side 20b opposite to the first side 20a. A plurality of first conductive bumps 21 are formed on the first side 20a. Moreover, a plurality of conductive vias 200 are formed in each of the plurality of electronic bodies 20, and the plurality of conductive vias 200 are electrically connected to the plurality of first conductive bumps 21. Each of the plurality of first conductive bumps 21 is, for example, a copper pillar or a metal pillar.

As shown in FIG. 2B, a reinforcing layer 23 is formed on the first side 20a to enhance the overall structural strength of each of the plurality of electronic bodies 20 and to avoid cracking of each of the plurality of electronic bodies 20 in subsequent processes.

In one embodiment, polyimide (PI) is coated on the first side 20a to form the reinforcing layer 23, wherein the height of each first conductive bump 21 is greater than the thickness of the reinforcing layer 23, so that each first conductive bump 21 protrudes and is exposed from the reinforcing layer 23. In one embodiment, the ratio of the thickness of the reinforcing layer 23 to the height of each of the first conductive bumps 21 is approximately 0.4~0.8.

As shown in FIG. 2C, one side (i.e., the first side 20a) of each of the plurality of electronic bodies 20 having the plurality of first conductive bumps 21 is disposed on a first carrier 25 via a first adhesive layer 250. That is, each of the plurality of electronic bodies 20 has a reinforcing layer 23 and a first adhesive layer 250 formed on the first side 20a to cover the plurality of first conductive bumps 21. Then, the second side 20b is thinned (for example, a grinding process is performed), so that the plurality of conductive vias 200 are exposed from the second side 20b. Each of the plurality of conductive vias 200 is, for example, a conductive through-silicon via (TSV).

As shown in FIG. 2D, a conductive circuit 24 is formed on the second side 20b of each of the plurality of electronic bodies 20 and electrically connected to the plurality of conductive vias 200, and a plurality of second conductive bumps 22 are formed on the conductive circuit 24, so that the plurality of second conductive bumps 22 can be electrically connected to the plurality of first conductive bumps 21 via the conductive circuit 24 and the plurality of conductive vias 200. Each of the second conductive bumps 22 includes, for example, a copper pillar and solder material.

As shown in FIG. 2E, one side (i.e., the first side 20b) of each of the plurality of electronic bodies 20 having the plurality of second conductive bumps 22 is disposed on a second carrier 26 via a second adhesive layer 260, and the first carrier 25 and the first adhesive layer 250 are removed, thereby allowing the plurality of first conductive bumps 21 to be exposed from the reinforcing layer 23.

As shown in FIG. 2F, one side (i.e., the first side 20a) of each of the plurality of electronic bodies 20 having the plurality of first conductive bumps 21 is disposed on a third carrier 26, and the second carrier 26 and the second adhesive layer 260 are removed. Then, a singulation process is performed to separate each of the plurality of electronic bodies 20 to obtain a plurality of electronic structures 2.

Through the aforementioned manufacturing method, the electronic structure 2 of the present disclosure comprises: an electronic body 20 having a first side 20a and a second side 20b opposite to the first side 20a; a plurality of first conductive bumps 21 formed on the first side 20a; a plurality of second conductive bumps 22 formed on the second side 20b; and a reinforcing layer 23 formed on the first side 20a, wherein a height of each of the plurality of first conductive bumps 21 is greater than a thickness of the reinforcing layer 23, so that each of the plurality of first conductive bumps 21 protrudes and is exposed from the reinforcing layer 23.

The reinforcing layer 23 is, for example, polyimide (PI), wherein the ratio of the thickness of the reinforcing layer 23 to the height of each of the plurality of first conductive bumps 21 is about 0.4~0.8.

In one embodiment, the electronic structure 2 may include a first adhesive layer 250 formed on the reinforcing layer 23, thereby allowing the reinforcing layer 23 and the first adhesive layer 250 to cover the plurality of first conductive bumps 21.

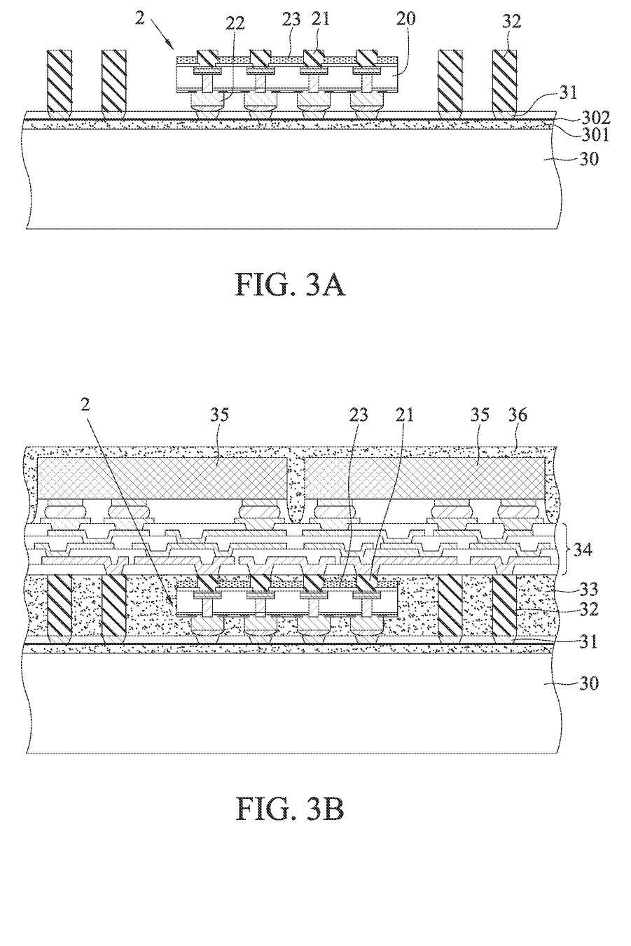

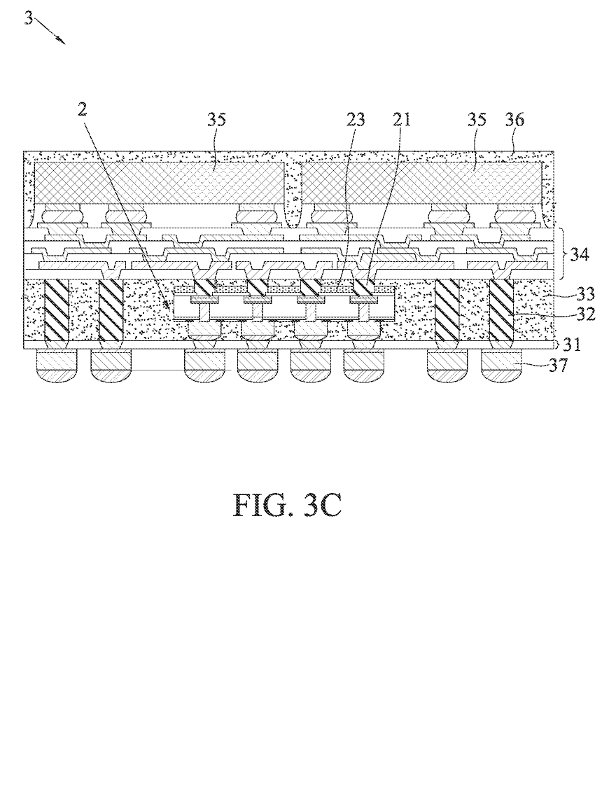

Please refer to FIG. 3A to FIG. 3C, which are schematic cross-sectional views illustrating a method for manufacturing an electronic package integrating the electronic structure of the present disclosure. The electronic structure is mainly used as a bridge component to be integrated into the electronic package.

As shown in FIG. 3A, a carrier 30 is provided, and a carrier structure 31, an electronic structure 2 and a plurality of conductive pillars 32 are arranged on the carrier 30.

The carrier 30 is, for example, a board of semiconductor material (e.g., silicon or glass), on which a release layer 301 and a metal layer 302, such as titanium/copper, are sequentially formed by, for example, coating, so that the carrier structure 31 is formed on the metal layer 302.

In one embodiment, the carrier structure 31 includes a dielectric layer and a circuit layer bonded to the dielectric layer. The dielectric layer is made of, for example, polybenzoxazole (PBO), polyimide (PI), prepreg (PP) or other dielectric materials, and the circuit layer and the dielectric layer can be formed by using a redistribution layer (RDL) process.

The electronic structure 2 is attached to the circuit layer of the carrier structure 31 via a plurality of second conductive bumps 22.

The conductive pillars 32 are disposed on the carrier structure 31 and are electrically connected to the circuit layer. In one embodiment, the conductive pillars 32 may be made of, for example, copper metal material or solder material.

As shown in FIG. 3B, a cladding layer 33 is formed on the carrier structure 31 and covers the electronic structure 2 and the conductive pillars 32. It should be understood that a portion of the cladding layer 33, a portion of each of the conductive pillars 32, and a portion of each of the first conductive bumps 21 can be removed via a leveling process (a grinding process), so that the end surfaces of the first conductive bumps 21 and the end surfaces of the conductive pillars 32 are exposed from and flush with the upper surface of the cladding layer 33.

In one embodiment, the cladding layer 33 is an insulating material, such as polyimide (PI), dry film, encapsulating colloid of epoxy or molding compound. For example, the cladding layer 33 may be formed on the carrier structure 31 by liquid compound, lamination or compression molding.

Next, a circuit structure 34 is formed on the cladding layer 33, thereby allowing the circuit structure 34 to be electrically connected to the plurality of conductive pillars 32 and the plurality of first conductive bumps 21.

In one embodiment, the circuit structure 34 includes an insulating layer and a redistribution layer (RDL) disposed on the insulating layer. The redistribution layer is electrically connected to the plurality of conductive pillars 32 and the plurality of first conductive bumps 21. Furthermore, the redistribution layer is made of copper, and the insulating layer can be made of, for example, polybenzoxazole (PBO), polyimide (PI), prepreg (PP), and the like.

Thereafter, a plurality of electronic components 35 are disposed on the circuit structure 34, and then an encapsulation layer 36 is used to encapsulate the electronic components 35.

In one embodiment, each of the electronic components 35 is an active component, a passive component, or a combination of the active component and the passive component. The active component is, for example, a semiconductor chip, and the passive component is, for example, a resistor, a capacitor, and an inductor. In one embodiment, each of the electronic components 35 is, for example, a semiconductor chip such as a graphics processing unit (GPU) or a high bandwidth memory (HBM) The electronic structure 2 serves as a bridge component (Bridge Die), which is electrically connected to the circuit structure 34 via the first conductive bumps 21 and thereby electrically bridges at least two of the electronic components 35.

In addition, the encapsulation layer 36 is made of an insulating material, such as polyimide (PI), dry film, or encapsulating colloid of epoxy or molding compound, and the encapsulation layer 36 can be formed on the circuit structure 34 by lamination or molding. It should be understood that the encapsulation layer 36 may be made of the same or different material from the cladding layer 33.

As shown in FIG. 3C, the carrier 30 and the release layer 301 thereon are removed, and then the metal layer 302 is removed to expose the carrier structure 31.

Next, a plurality of conductive components 37 are formed on the carrier structure 31 and electrically connected to the circuit layer. Then, a singulation process is performed to produce the electronic package 3, so that the electronic package 3 can subsequently be disposed on an external electronic device such as a package substrate or a circuit board via the conductive components 37. In one embodiment, each of the conductive components 37 includes a metal bump such as copper and a solder material formed on the metal bump.

To sum up, in the electronic structure and the manufacturing method thereof of the present disclosure, a reinforcing layer is formed on the first side of the electronic body provided with a plurality of first conductive bumps, thereby allowing the height of each first conductive bump to be greater than the thickness of the reinforcing layer. Accordingly, each of the first conductive bumps protrudes and is exposed from the reinforcing layer, so as to improve the overall strength of the electronic structure via the reinforcing layer, reduce warpage problems, and avoid the problem of cracks caused by the electronic body being too thin during the subsequent manufacturing process. In addition, the electronic structure and the electronic package and the manufacturing method thereof of the present disclosure can be completed using existing manufacturing processes and equipment, without a large amount of additional costs.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic structure, comprising:
an electronic body having a first side and a second side opposite to the first side;
a plurality of first conductive bumps formed on the first side;
a plurality of second conductive bumps formed on the second side; and
a reinforcing layer formed on the first side, wherein a height of each of the plurality of first conductive bumps is greater than a thickness of the reinforcing layer, so that each of the plurality of first conductive bumps protrudes and is exposed from the reinforcing layer.

2. The electronic structure of claim 1, wherein a plurality of conductive vias are formed in the electronic body.

3. The electronic structure of claim 2, wherein the plurality of second conductive bumps are electrically connected to the plurality of first conductive bumps via the plurality of conductive vias.

4. The electronic structure of claim 1, wherein the plurality of first conductive bumps and the plurality of second conductive bumps are metal pillars.

5. The electronic structure of claim 1, wherein a ratio of the thickness of the reinforcing layer to the height of each of the plurality of first conductive bumps is 0.4~0.8.

6. The electronic structure of claim 1, further comprising an adhesive layer formed on the reinforcing layer, so that the reinforcing layer and the adhesive layer cover the plurality of first conductive bumps.

7. The electronic structure of claim 1, wherein the electronic structure serves as a bridge component for electrically connecting at least two electronic components.

8. A method for manufacturing an electronic structure, comprising:
providing an electronic body having a first side and a second side opposite to the first side, wherein a plurality of first conductive bumps are formed on the first side;
forming a reinforcing layer on the first side, wherein a height of each of the plurality of first conductive bumps is greater than a thickness of the reinforcing layer, so that each of the plurality of first conductive bumps protrudes and is exposed from the reinforcing layer; and
forming a plurality of second conductive bumps on the second side, and electrically connecting the plurality of second conductive bumps to the plurality of first conductive bumps.

9. The method of claim 8, wherein a plurality of conductive vias are formed in the electronic body.

10. The method of claim 9, wherein the plurality of second conductive bumps are electrically connected to the plurality of first conductive bumps via the plurality of conductive vias.

11. The method of claim 8, wherein the plurality of first conductive bumps and the plurality of second conductive bumps are metal pillars.

12. The method of claim 8, wherein a ratio of the thickness of the reinforcing layer to the height of each of the plurality of first conductive bumps is 0.4~0.8.

13. The method of claim 8, further comprising forming an adhesive layer on the reinforcing layer, so that the reinforcing layer and the adhesive layer cover the plurality of first conductive bumps.

14. The method of claim 8, wherein the electronic structure serves as a bridge component for electrically connecting at least two electronic components.

15. The method of claim 8, further comprising disposing the first side of the electronic body on a first carrier via a first adhesive layer, wherein the plurality of first conductive bumps are formed on the first side, and then thinning the second side, thereby exposing a plurality of conductive vias in the electronic body from the second side.

16. The method of claim 15, further comprising forming a conductive circuit on the second side of the electronic body and electrically connecting the conductive circuit to the conductive vias, and forming the plurality of second conductive bumps on the conductive circuit, thereby electrically connecting the plurality of second conductive bumps to the plurality of first conductive bumps via the conductive circuit and the plurality of conductive vias.

17. The method of claim 16, further comprising disposing the second side of the electronic body on a second carrier via a second adhesive layer, wherein the plurality of second conductive bumps are formed on the second side, and then removing the first carrier and the first adhesive layer, thereby exposing the plurality of first conductive bumps from the reinforcing layer.

18. The method of claim 17, further comprising disposing the first side of the electronic body on a third carrier, wherein the plurality of first conductive bumps are formed on the first side, and then removing the second carrier and the second adhesive layer.
